(19) United States
(12) Patent Application Publication
(10) Pub. No.: US 2017/0270767 A1
(43) Pub. Date: Sep. 21, 2017

(54) METHOD AND APPARATUS FOR MANAGING CASE ALERTS

(71) Applicant: General Electric Company, Schenectady, NY (US)

(72) Inventor: David Sean FARRELL, San Ramon, CA (US)

(21) Appl. No.: 15/071,266

(22) Filed: Mar. 16, 2016

(51) Int. Cl. G08B 21/18; G01R 19/00

(52) U.S. Cl. CPC G08B 21/18; G01R 19/0038

(57) ABSTRACT

Approaches are provided for an apparatus having an interface with an input. The input is configured to receive a plurality of current alerts. The apparatus further includes a display device configured to display the current alerts, and a memory configured to store a prior case data structure comprising prior evidence alerts. The apparatus further includes a processor configured to access the prior case data structure from the memory. The processor is further configured to determine whether the prior evidence alerts include a first prior evidence alert related to the first current alert and a second prior evidence alert related to the second current alert. In response to determining the prior evidence alerts include the first and second prior evidence alerts, the processor is further configured to display at the display device an indication of a prior relationship between the first current alert and the second current alert.

### BACKGROUND

Technical Field

The subject matter disclosed herein generally relates to management of case alerts. More specifically, the subject matter relates to suggesting case alerts in a current case based on case alerts issued in a prior case.

Brief Description of the Related Art

In industrial operations, industrial machines and systems are monitored to ensure proper operation and/or detect anomalies which may arise. Remote Monitoring & Diagnostic (M&D) approaches often include personnel at one location communicating with personnel at an operating site located at a separate, geographically remote location. The M&D personnel view information related to industrial machines or systems located at the operating site.

During operation, problems oftentimes occur which may warrant an operator or maintenance engineer's involvement. In many occasions, sensors or analytic systems produce alerts in response to detecting abnormalities in the industrial machine or system. The alerts may or may not be related to the underlying abnormality. Thus, M&D personnel in many instances must manually review the alerts to determine their relevancy.

The above-mentioned problems have resulted in some user dissatisfaction with previous approaches, inefficient case resolution, and sub-optimal application of remote monitoring and diagnostic approaches.

### BRIEF DESCRIPTION OF THE DISCLOSURE

The approaches described herein provide for a method that includes receiving a plurality of current alerts generated in response to an abnormality detected in an industrial machine or system. The abnormality in some aspects is detected at at least one sensor at the industrial machine or system. The current alerts include a first current alert and a second current alert.

The method further includes accessing a prior case data structure from a memory device. The prior case data structure is generated from a case that has been closed. The prior case data structure includes prior evidence alerts.

The method further includes determining whether the prior evidence alerts include a first prior evidence alert related to the first current alert and a second prior evidence alert related to the second current alert.

In some aspects, a prior evidence alert is related to a current alert when the prior evidence alert and the current alert relate to a common sensor type. In other aspects, a prior evidence alert is related to a current alert when the prior evidence alert and the current alert relate to a common industrial machine or system type. In still other aspects, a prior evidence alert is related to a current alert when the prior evidence alert and the current alert relate to a common failure type.

The method further includes, in response to determining the prior evidence alerts include the first prior evidence alert and the second prior evidence alert, displaying an indication of a prior relationship between the first current alert and the second current alert on a display device.

In another aspect, an apparatus includes an interface with an input. The input is configured to receive a plurality of current alerts generated in response to one or more abnormalities detected in an industrial machine or system. The plurality of current alerts include a first current alert and a second current alert. In some aspects, the abnormality is detected at at least one sensor at the industrial machine or system.

The apparatus further includes a display device configured to display the plurality of current alerts. The apparatus further includes a memory configured to store a prior case data structure comprising prior evidence alerts. The prior case data structure is generated from a case that has been closed.

The apparatus further includes a processor coupled to the interface, the display device, and the memory. The processor is configured to access the prior case data structure from the memory. The processor is further configured to determine whether the prior evidence alerts include a first prior evidence alert related to the first current alert and a second prior evidence alert related to the second current alert.

In some aspects, a prior evidence alert is related to a current alert when the prior evidence alert and the current alert relate to a common sensor type. In other aspects, a prior evidence alert is related to a current alert when the prior evidence alert and the current alert relate to a common industrial machine or system type. In still other aspects, a prior evidence alert is related to a current alert when the prior evidence alert and the current alert relate to a common failure type.

In response to determining the prior evidence alerts include the first prior evidence alert and the second prior evidence alert, the processor is further configured to display at the display device an indication of a prior relationship between the first current alert and the second current alert.

### BRIEF DESCRIPTION OF THE DRAWINGS

For a more complete understanding of the disclosure, reference should be made to the following detailed description and accompanying drawings wherein:

FIG. 1 comprises an illustration of an informational flow chart for providing information relating to industrial machines or systems according to various embodiments of the present invention;

FIG. 2 comprises a block diagram illustrating an exemplary display and an exemplary case data structure for managing information relating to industrial machines or systems according to various embodiments of the present invention;

FIG. 3 comprises an operational flow chart illustrating an approach for case management according to various embodiments of the present invention; and

FIG. 4 comprises a block diagram illustrating an exemplary apparatus for managing information relating to industrial machines or systems according to various embodiments of the present invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION OF THE DISCLOSURE

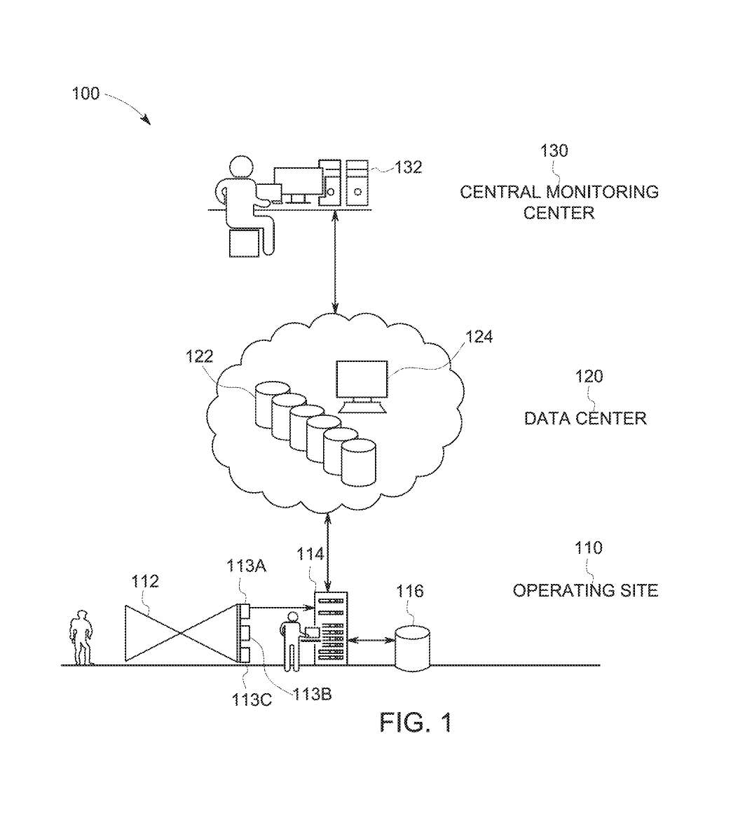

Referring now to FIG. 1, a system 100 for monitoring industrial machines includes an operating site 110, optionally, a data center 120, and a central monitoring center 130. The operating site 110 includes one or more industrial machines, equipment, or systems of industrial machines or equipment 112. Examples of industrial machines 112 monitored in system 100 include aircraft machinery (e.g., turbine engines), marine machinery, mining machinery, oil machinery, gas machinery, health care machinery, telecom machinery, to mention a few examples. Other examples are possible.

One or more sensors 113a, 113b, 113c are associated with the industrial machine 112. The sensors 113a, 113b, 113c may be physically connected to the industrial machine 112 or may be remote from the industrial machine. In either approach, the sensors 113a, 113b, 113c are capable of sensing operational characteristics of the industrial machine 112. Operational characteristics may include a measured temperature, a measured vibration, a measured pressured, a calculated efficiency, a structural defect, a lifespan of machine, a machine history, and/or a detected position shift. Other examples are possible.

Industrial machine 112 is operably connected to a local computing device 114 such that the computing device 114 receives or obtains information from the industrial machine 112 or sensors 113a, 113b, 113c associated with the industrial machine 112. The computing device 114 may be continuously connected to the industrial machine 112 or sensors 113a, 113b, 113c, or may be removably connected to the industrial machine 112 or sensors 113a, 113b, 113c. In one approach, the computing device 114 is located at the operating site 110. In other approaches, the computing device 114 is instead located remotely from the industrial machine 112. Information received at the computing device 114 from the industrial machine 112 or sensors 113a, 113b, 113c includes operational characteristics of the industrial machine 112.

The computing device 114 may be any type of hardware device such as a personal computer, a tablet, a cellular telephone, and/or a personal digital assistant. Other examples are possible. The computing device 114 may include a processor, an interface (e.g., a computer based program and/or hardware) having an input (which may also include a user input) and an output, a memory, and a display device (e.g., a screen or a graphical user interface which allows for a visualization to be made). In this way, a user of the computing device 114 is able to observe information at the computing device 114 (such as operational characteristics of the industrial machine 112), input information into the computing device 114, send information from the computing device 114 to a remote device (such as at the data center 120 or the central monitoring center 130), and receive information from a remote device. The computer device 114 may be configured to run specific software applications, such as a historian.

The computing device 114 is operably connected to a data storage module 116. The data storage module 116 includes a memory for short- and/or long-term storage of information received from the computing device 114. Examples of information received and stored at the data storage module 116 include historical information relating to the industrial machine 112, or information received at the computing device from a remote device (such as at the data center 120 or the central monitoring center 130).

The optional data center 120 is in communication with the operating site 110 (preferably, with the computing device 114 at the operating site) such that the data center 120 can send and/or receive information pertaining to one or more industrial machines 112 located at the operating site 110. The data center 120 maybe located at the operating site 110, at the central monitoring center 130, or in a location geographically remote from the operating site 110 and the central monitoring center 130. In one approach, the data center 120 is disposed on a cloud based network.

The data center 120 includes one or more data storage modules 122 having corresponding memories. The data center 120 may also include one or more computing devices 124 that include a processor, an interface having an input (which may include a user input) and an output, a memory, and a display device (e.g., a screen or a graphical user interface which allows for a visualization to be made). Various applications may be performed at the data center 120, including analytic modeling, anomaly detection, and/or calculations of key performance indicators.

The central monitoring center 130 includes a computing device 132 that is in communication with the data center 120 such that the central monitoring center 130 can send and/or receive information pertaining to one or more industrial machines 112 located at the operating site 110. Alternatively, the central monitoring center 130 is in communication with the operating site 110 (preferably, with the computing device 114 at the operating site) such that the central monitoring center 130 can send and/or receive information pertaining to one or more industrial machines 112 located at the operating site 110.

In one example of the operation of the system of 100 of FIG. 1, sensors 113a, 113b, 113c associated with an industrial machine 112 such as a gas turbine may detect various operational characteristics. Sensor 113a may detect operational characteristics relating to rotor balance within the gas turbine. Sensor 113b may detect operational characteristics relating to compression within the gas turbine. Sensor 113c may detect operational characteristics relating to temperature within the gas turbine. When an anomaly, abnormality, or incident occurs in the industrial machine 112, a computing device (e.g., computing device 114 located at the operating site 110, or computing device 132 located at a central monitoring center 130) records one or more alerts. The alerts are generated in response to the sensors 113a, 113b, 113c detecting operational characteristics that exceed or fall below a predetermined limit, or that fall outside of a predetermined range. Some of the alerts are related to the underlying abnormality, while others are unrelated to the underlying abnormality.

The current alerts are received at, for example, the computing device 132 at the central monitoring center 130. Current alerts correspond to a current, unresolved, and/or open case. For example, the current case may relate to anomalies detected at a gas turbine at operating site 110, where the cause of the anomalies is currently unknown.

In response to receiving the alerts, the computing device 132 accesses a prior case data structure from a memory device (e.g., data center 120). The prior case data structure includes prior evidence alerts. A prior evidence alert corresponds to an alert having been added as evidence to a prior, resolved, and closed case. For example, the prior case may relate to anomalies detected two years ago in a gas turbine model similar to that of the current case. Unlike the current case, the cause of the anomalies was determined and correct. Thus, the prior case was resolved and closed.

The computing device 132 determines whether any current alerts are related to each other based upon the existence of related prior evidence alerts in a prior case data structure. More particularly, the computing device 132 determines whether the prior evidence alerts include a first prior evidence alert related to the first current alert and a second prior evidence alert related to the second current alert. In some aspects, a prior evidence alert is related to a current alert when the prior evidence alert and the current alert relate to a common sensor type. In other aspects, a prior evidence alert is related to a current alert when the prior evidence alert and the current alert relate to a common industrial machine or system type. In still other aspects, a prior evidence alert is related to a current alert when the prior evidence alert and the current alert relate to a common failure type.

When the current alerts are determined to be related via prior case participation, the computing device 132 displays, for example on a monitor, an indication to a user that the current alerts are related via a prior case. In some approaches, the current alert is bound to a current case data structure.

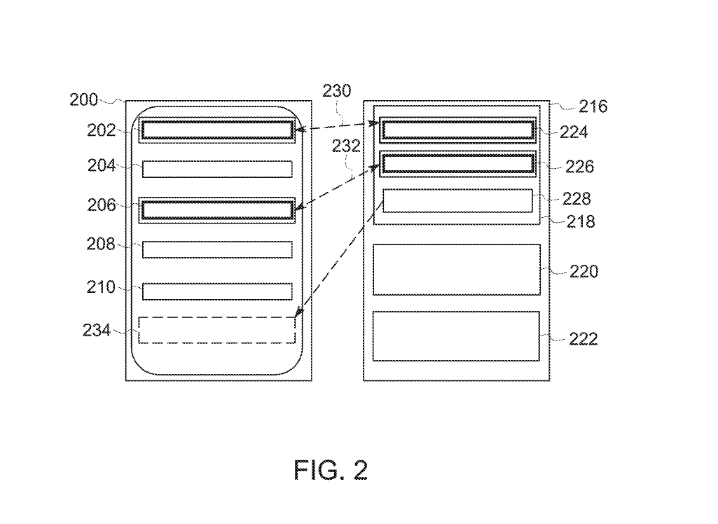

As discussed, the alerts are presented to a user at a display device. In one example, with reference to FIG. 2, a display device 200 displays current alerts 202, 204, 206, 208, and 210. The display device 200 may be located, for example, at computing device 132 at the central monitoring center 130. The display device 200 may be a liquid crystal display screen, a light-emitting diode backlit liquid crystal display screen, or other screen capable of conveying information. The display device may be at, for example, a desktop computer, a laptop computer, a tablet, or a smartphone.

The current alerts 202, 204, 206, 208, and 210 are generated in response to sensors associated with an industrial machine detecting operational characteristics that exceed or fall below a predetermined limit, or that fall outside of a predetermined range. The current alerts are generated, for example, at computing device 114 at operating site 110, and are received, for example, at computing device 132 at the central monitoring center 130.

The displayed current alerts may include alerts unrelated to an underlying abnormality detected in an industrial machine or system, as well as at least one alert generated in response to the abnormality. In the example of FIG. 2, alert 202 indicates rotor imbalance on the gas turbine, alert 204 indicates a high operational temperature at a first location of the gas turbine, alert 206 indicates a compression issue on the gas turbine, alert 208 indicates a high operational temperature at a second location of the gas turbine, and alert 210 indicates a high operational temperature at a third location of the gas turbine. The number of current alerts may range from one to many.

In some occasions, similar problems have previously occurred on a given industrial machine or a similar industrial machine. Prior cases having the same or similar problem type and/or the same or similar machine type (i.e., “past like-cases”), including past similar alerts as declared evidence within those cases, may inform an analyst in assessing alerts pertaining to a current problem with an industrial machine. More specifically, one or more current alerts which have been related previously in cases may inform an analyst that alerts received in a current problem have previously been deemed related to the underlying abnormality.

In this regard, a computing device (such as computing device 132 at the central monitoring center 130) retrieves at least one prior case data structure (for example, from data center 120), and automatically suggest to an analyst one or more alerts to review together based on alerts related in past like-cases. In the example of FIG. 2, prior case data structure 216 is deemed a past like-case because it was previously created in response to an abnormality detected on a gas turbine model similar to the gas turbine from which the alerts 202-210 originated. As used herein, a “case” is associated with an anomaly, an abnormality, or an incident detected in an industrial machine or system, and a “case data structure” includes a data structure that represents a compilation of characteristics of the case. Prior case data structure 216 includes an evidence field 218 with stored evidence and, for example, an interpretation field 220 with a stored interpretation and a recommendation field 222 with a stored recommendation.

The evidence field 218 of the prior case data structure 216 includes one or more alerts that were previously deemed relevant in the assessment and resolution of a prior case. In the example of FIG. 2, the evidence field 218 contains prior alert 224, prior alert 226, and prior alert 228.

As discussed in greater detail elsewhere herein, a computing device determines, based upon the prior alerts, whether the current alerts have had a prior relationship. This determination is based upon whether the prior alerts include a first prior alert related to a first current alert and a second prior alert related to a second current alert. In some aspects, a prior alert is related to a current alert when the prior alert and the current alert relate to a common sensor type. In other aspects, a prior alert is related to a current alert when the prior alert and the current alert relate to a common industrial machine or system type. In still other aspects, a prior alert is related to a current alert when the prior alert and the current alert relate to a common failure type. When the first and second current alerts have related prior alerts in a single prior case, the first and second current alerts are determined to have a prior relationship.

In the example of FIG. 2, the computing device (not shown) determines current alert 202 and prior alert 224 have a relationship 230. The computing device further determines current alert 206 and prior alert 226 have a relationship 232. In response to these determinations, the computing device graphically highlights the display of current alert 202 and current alert 206 on the display device 200, as shown in FIG. 2. The graphical highlighting may be in the form suitable for indicating current alerts 202, 206 have a likely relationship with each other due to prior association in a case, versus the alerts 204, 208, 210 that do not. For example, the graphical highlighting can include a static graphical indication (e.g., an icon), a dynamic graphical indication (e.g., a moving icon), a change in font, font size, or font style. Other example are possible.

In this way, a user is alerted that current alert 202 (indicating rotor imbalance on the gas turbine) and current alert 206 (indicating a compression issue on the gas turbine) have previously been deemed relevant in resolving an abnormality in a similar model gas turbine. The user can then prioritize these alerts 202, 206 with respect to the alerts 204, 208, 210, which indicate a high operational temperature at three locations of the gas turbine, and ensure alerts 202, 206 are analyzed holistically to understand the different facets of the threat.

In some approaches, the computing device (not shown) is further configured to display at the display device 200 a new alert 234. The new alert 234 is based on an alert 228 that does not have a relationship with an alert of the current case. This new alert 234 may allow a user to prepare for an anticipated alert, or may inform the user to perform a manual inspection of the industrial machine based on the information of the prior alert 228.

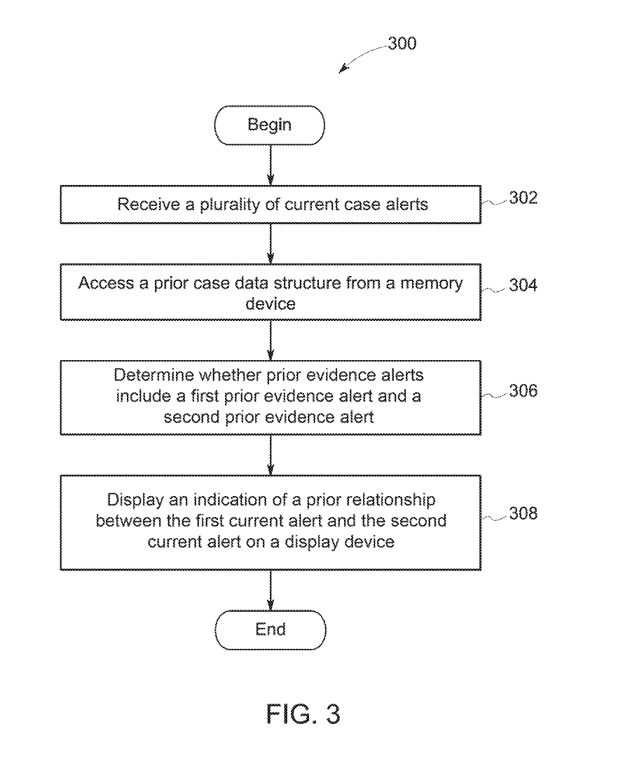

With reference now to FIG. 3, a method 300 includes receiving 302 a plurality of current alerts generated in response to one or more abnormalities detected in an industrial machine or system. The plurality of current alerts including a first current alert and a second current alert. In some aspects, the alerts are generated, in response to sensors associated with the industrial machine detecting operational characteristics that exceed or fall below a predetermined limit, or that fall outside of a predetermined range. The alerts are generated, for example, at computing device 114 at operating site 110, and are received, for example, at computing device 132 at the central monitoring center 130.

The method 300 further includes accessing 304 a prior case data structure from a memory device. The prior case data structure may be accessed, for example, from data storage modules 122 at a data center 120. The prior case data structure includes prior alerts in its evidence set. The prior case data structure is preferably generated from a case that has been closed. Any suitable number of prior case data structures may be selectively accessed from the memory device.

The method 300 further includes determining 306 whether the prior evidence alerts include a first prior evidence alert related to the first current alert and a second prior evidence alert related to the second current alert. In some aspects, a prior evidence alert is related to a current alert when the prior evidence alert and the current alert relate to a common sensor type (e.g., sensor 113a of FIG. 1). For example, a first prior evidence alert and the first current alert may originate from a similar or the same temperature sensor associated with a gas turbine. In other aspects, a prior evidence alert is related to a current alert when the prior evidence alert and the current alert relate to a common industrial machine or system type (e.g., industrial machine 112 of FIG. 1). For example, a second prior evidence alert and the second current alert may originate from a similar or the same gas turbine. In still other aspects, a prior evidence alert is related to a current alert when the prior evidence alert and the current alert relate to a common failure type. For example, a first prior evidence alert and the first current alert may originate from a similar or the same rotor imbalance failure. In other aspects, a prior evidence alert is related to a current alert based upon common underlying data (e.g., a measured temperature, a measured vibration, a measured pressured, a calculated efficiency, a structural defect, a lifespan of machine, a machine history, and/or a detected position shift). Other examples are possible.

The determination of whether the prior evidence alerts include the first prior evidence alert and the second prior evidence alert may be performed, for example, at computing device 132 at the central monitoring center 130. For example, the computing device 132 may be programmed with the criteria (such as the identity of the sensor). The computing device 132 may determine whether the same sensor was utilized for a current and a prior case alert.

When the prior evidence alerts include the first prior evidence alert and the second prior evidence alert, the method 300 further includes displaying 308 an indication of a prior relationship between the first current alert and the second current alert on a display device. As used herein, the first and second current alerts have a “prior relationship” when the first and second current alerts both have related prior alerts in a single prior case.

The indication may be displayed at a display device located, for example, at computing device 132 at the central monitoring center 130. In some approaches, the display includes graphically highlighting the deemed-related alerts on the display device. The current alerts may be graphically highlighted by visually differentiating them and their relationship from other non-related alerts. This may be done, for example, by visual highlighting, physical grouping, or by providing a graphical symbol near their display. In some approaches, informational messages (such as an email or text message) may be generated in order to selectively identify the related alerts. Other examples are possible.

By graphically highlighting the relationship between alerts, a user is informed that a similar alert was previously determined to be related to an underlying abnormality for which a prior case data structure was created. The user is further informed that, among the many current alerts displayed on the displace device, the related alerts may be of greater interest to assess together in a current case.

In some approaches, the method further includes binding the current related alerts to a current case data structure. By “binding,” and as used herein, it is meant to associate a first software routine or module with a second software routine or module. For example, the second software module (e.g., a case data structure) may include a template portion that is replaced or augmented with the first software module (e.g., the current related alerts) upon association. The association is typically carried out by a processor device either automatically or in response to receiving a user input.

The binding may be performed, for example, in response to receiving a user selection of the current related alerts. The user selection may be performed in response to a user determining that current alerts are related and relevant to the current case. In one aspect, the user selection is performed when a user selects a visual representation of the prior case and its evidence alert.

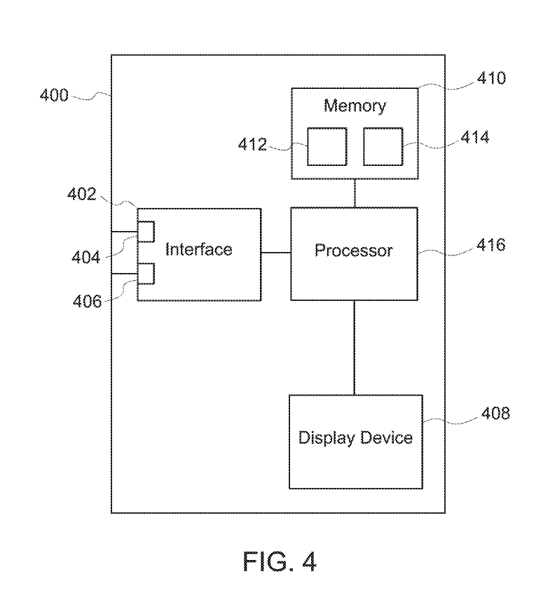

With reference now to FIG. 4, an apparatus 400 (such as computing device 132 of FIG. 1) an interface 402 including an input 404 (which preferably includes a user input) and an output 406. The input 402 is configured to receive a plurality of current alerts generated in response to one or more abnormalities detected in an industrial machine or system.

The apparatus 400 also includes a display device 408 configured to convey information to a user, such as the plurality of current alerts received at the input 404. The display device 408 may be a liquid crystal display screen, a light-emitting diode backlit liquid crystal display screen, or other screen capable of conveying information.

The apparatus 400 further includes a memory device 410. The memory may be any suitable type of memory, including volatile or nonvolatile memories such as random access memory (RAM), dynamic RAM (DRAM), synchronous RAM (SRAM), read only memory (ROM), programmable ROM (PROM), erasable PROM (EPROM), electrically erasable PROM (EEPROM), non-volatile RAM (NVRAM), flash memory, solid state drives (SSD), embedded Multi-Media Card (eMMC). The memory device 410 stores a prior case data structure 412 that includes prior evidence alerts. As discussed, the prior case data structure 412 is generated from a case that has been closed. In some aspects, the memory device 410 stores a plurality of prior case data structures 412, 414.

The apparatus 400 also includes a processor 416. The processor 416 is coupled to the interface 402, the display device 408, and the memory device 410. The processor 416 is configured to access the prior case data structure 412 from the memory 410. The processor 416 is further configured to determine whether the prior evidence alerts include a first prior evidence alert related to the first current alert and a second prior evidence alert related to the second current alert. In some aspects, a prior evidence alert is related to a current alert when the prior evidence alert and the current alert relate to a common sensor type. In other aspects, a prior evidence alert is related to a current alert when the prior evidence alert and the current alert relate to a common industrial machine or system type. In still other aspects, a prior evidence alert is related to a current alert when the prior evidence alert and the current alert relate to a common failure type. In other aspects, a prior evidence alert is related to a current alert based upon common underlying data (e.g., a measured temperature, a measured vibration, a measured pressured, a calculated efficiency, a structural defect, a lifespan of machine, a machine history, and/or a detected position shift). Other examples are possible.

When the prior evidence alerts include the first prior evidence alert and the second prior evidence alert, the processor is further configured to display at the display device 408 an indication of a prior relationship between the first current alert and the second current alert. As previously discussed, the first and second current alerts have a “prior relationship” when the first and second current alerts both have related prior alerts in a single prior case.

In some approaches, the display of the indication includes a graphical highlight of the alerts on the display device 408. They may be graphically highlighted by visually differentiating the related alerts from other alerts. This may be done, for example, by visual highlighting, by grouping, or by providing a graphical symbol near their display in an alerts listing. In some approaches, informational messages (such as an email or text message) may be generated in order to selectively identify the related alerts. Other examples are possible.

In some approaches, processor 416 is further configured to bind the current related alerts to a current case data structure. The binding may be performed, for example, in response to receiving at the input 404 a user selection of the current alert. The user selection may be performed in response to a user determining the current alerts are indeed relevant to the current case. In one aspect, the user selection is performed when a user selects a visual representation highlighting the relationships.

Preferred embodiments of this invention are described herein, including the best mode known to the inventors for carrying out the invention. It should be understood that the illustrated embodiments are exemplary only, and should not be taken as limiting the scope of the invention.

What is claimed is:

1. A method comprising:
receiving a plurality of current alerts generated in response to one or more abnormalities detected in an industrial machine or system, the plurality of current alerts including a first current alert and a second current alert;
accessing a prior case data structure from a memory device, the prior case data structure including prior evidence alerts, the prior case data structure generated from a case that has been closed;
determining whether the prior evidence alerts include a first prior evidence alert related to the first current alert and a second prior evidence alert related to the second current alert;
in response to determining the prior evidence alerts include the first prior evidence alert and the second prior evidence alert, displaying an indication of a prior relationship between the first current alert and the second current alert on a display device.

2. The method of claim 1, wherein the displaying the indication of the prior relationship includes graphically highlighting the first current alert and the second current alert on the display device.

3. The method of claim 1, further comprising:
detecting the one or more abnormalities at at least one sensor at the industrial machine or system.

4. The method of claim 1 wherein the first prior evidence alert is related to the first current alert when the first prior evidence alert and the first current alert relate to a common sensor type.

5. The method of claim 1 wherein the second prior evidence alert is related to the second current alert when the second prior evidence alert and the second current alert relate to a common sensor type.

6. The method of claim 1 wherein the first prior evidence alert is related to the first current alert when the first prior evidence alert and the first current alert relate to a common industrial machine or system type.

7. The method of claim 1 wherein the second prior evidence alert is related to the second current alert when the second prior evidence alert and the second current alert relate to a common industrial machine or system type.

8. The method of claim 1 wherein the first prior evidence alert is related to the first current alert when the first prior evidence alert and the first current alert relate to a common failure type.

9. The method of claim 1 wherein the second prior evidence alert is related to the second current alert when the second prior evidence alert and the second current alert relate to a common failure type.

10. An apparatus comprising:
an interface with an input, the input configured to receive a plurality of current alerts generated in response to one or more abnormalities detected in an industrial machine or system, the plurality of current alerts including a first current alert and a second current alert;
a display device configured to display the plurality of current alerts;
a memory configured to store a prior case data structure comprising prior evidence alerts, the prior case data structure generated from a case that has been closed; and
a processor coupled to the interface, the display device, and the memory, the processor configured to access the prior case data structure from the memory, the processor configured to determine whether the prior evidence alerts include a first prior evidence alert related to the first current alert and a second prior evidence alert related to the second current alert, wherein in response to determining the prior evidence alerts include the first prior evidence alert and the second prior evidence alert, the processor is further configured to display at the display device an indication of a prior relationship between the first current alert and the second current alert.

11. The apparatus of claim 10 wherein the processor is further configured graphically highlight the first current alert and the second current alert on the display device.

12. The apparatus of claim 10 wherein the one or more abnormalities are detected at at least one sensor at the industrial machine or system.

13. The apparatus of claim 10 wherein the first prior evidence alert is related to the first current alert when the first prior evidence alert and the first current alert relate to a common sensor type.

14. The apparatus of claim 10 wherein the second prior evidence alert is related to the second current alert when the second prior evidence alert and the second current alert relate to a common sensor type.

15. The apparatus of claim 10 wherein the first prior evidence alert is related to the first current alert when the first prior evidence alert and the first current alert relate to a common industrial machine or system type.

16. The apparatus of claim 10 wherein the second prior evidence alert is related to the second current alert when the second prior evidence alert and the second current alert relate to a common industrial machine or system type.

17. The apparatus of claim 10 wherein the first prior evidence alert is related to the first current alert when the first prior evidence alert and the first current alert relate to a common failure type.

18. The apparatus of claim 10 wherein the second prior evidence alert is related to the second current alert when the second prior evidence alert and the second current alert relate to a common failure type.
